(19) United States
(12) Patent Application Publication
(10) Pub. No.: US 2014/0372081 A1
(43) Pub. Date: Dec. 18, 2014

(54) REAL TIME ARTIFACT REMOVAL

(71) Applicants: Meltem Alkan Izzetoglu, Drexel Hill, PA (US); Kurtulus Izzetoglu, Drexel Hill, PA (US)

(72) Inventors: Meltem Alkan Izzetoglu, Drexel Hill, PA (US); Kurtulus Izzetoglu, Drexel Hill, PA (US)

(73) Assignee: Drexel University, Philadelphia, PA (US)

(21) Appl. No.: 14/007,815

(22) PCT Filed: Mar. 29, 2012
(86) PCT No.: PCT/US12/31074

§ 371 Date: Dec. 12, 2013

Related U.S. Application Data
(60) Provisional application No. 61/468,750, filed on Mar. 29, 2011.

(51) Int. Cl. G01R 23/15

(52) U.S. Cl. CPC G01R 23/15
USPC 702/193

(57) ABSTRACT

Noise artifacts may be removed from a signal utilizing functional near infrared (fNIR) spectroscopy measurement techniques. The noise removal may be accomplished in field conditions, such as, for example, in an operating room setting. In an example configuration, to remove noise artifacts, independent component analysis (ICA) and principal component analysis (PCA) may be implemented in a procedure that utilizes a dark current measurement as a reference signal. The use of the combined ICA/PCA analysis and dark current measurement reference signal allows noise to be removed on a per channel basis, thus providing an effective noise removal procedure and allowing for a single active measurement channel.

### CROSS REFERENCE TO RELATED APPLICATIONS

The instant application claims priority to U.S. provisional patent application No. 61/468,750, entitled “Real Time Artifact Removal,” filed Mar. 29, 2011, which is hereby incorporated by reference in its entirety.

### GOVERNMENT RIGHTS

This invention was made with government support under grant number W81XWH-08-2-0573 awarded by the United States Army Medical Research and Material Command (USAMRMC)/Telemedicine & Advanced Technology Research Center (TATRC) and grant number W81XWH-09-2-0104 awarded by the USAMRMC/TATRC. The government has certain rights in the invention.

### TECHNICAL FIELD

The technical field generally is related to removing noise from signals, and more specifically is related to processing techniques for removing noise from signals measured via functional near infrared (fNIR) spectroscopy.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A data acquisition method and technique for removing noise artifacts from a relevant signal are disclosed. In one embodiment, a data acquisition method and an artifact removal procedure that allows functional near infrared (fNIR) spectroscopy to measure signals under field conditions, for example in an operating room setting, are disclosed. To remove the noise artifacts, independent component analysis (ICA) and principal component analysis (PCA) may be implemented in a procedure that utilizes a dark current measurement as a reference signal. As is described below, the use of the combined ICA/PCA analysis and dark current measurement reference is more effective than traditional noise removal techniques. Further, the use of the dark current reference signal allows noise to be removed on a per channel basis, both increasing the effectiveness of the noise removal procedure and allowing for a single active measurement channel.

### BRIEF DESCRIPTION OF THE DRAWINGS

FIG. 1 illustrates an example measurement signal sensor arrangement.

FIG. 2 is a flow diagram of an exemplary process for removing noise from a signal.

FIG. 3 is another flow diagram of example noise removal technique in accordance with an embodiment.

FIG. 4A illustrates an example relationship between a dark current reference signal and a fNIR spectroscopy signal.

FIG. 4B illustrates another example relationship between a dark current reference signal and a fNIR spectroscopy signal.

FIG. 4C illustrates another example relationship between a dark current reference signal and a fNIR spectroscopy signal.

FIG. 4D illustrates another example relationship between a dark current reference signal and a fNIR spectroscopy signal.

FIG. 5 illustrates a diagram of an adaptive filtering technique for removing noise artifacts from a signal.

FIG. 6A illustrates example results of several noise removals techniques relative to the same underlying source signal.

FIG. 6B is another example illustration of results of several noise removals techniques relative to the same underlying source signal.

FIG. 7 illustrates the correlation between a reference signal and intensity measurements using different noise removal techniques.

FIG. 8A illustrates an example result of ICA and PCA analyses performed on a measured signal.

FIG. 8B illustrates another example result of ICA and PCA analyses performed on a measured signal.

FIG. 9 illustrates an exemplary computing device which may implement aspects of the artifact removal procedure.

### DETAILED DESCRIPTION OF ILLUSTRATIVE EMBODIMENTS

Disclosed herein are techniques for removing noise artifacts from a signal of interest. Although aspects of the techniques will be described with reference to example embodiments, one skilled in the art can appreciate that the disclosed techniques may be applied in a variety of settings to many different types of signals. An exemplary application of the technique is through use of fNIR spectroscopy neuroimaging that may measure hemodynamic changes in the brain. As a result of cerebral energy metabolism, changes in cerebral oxygen consumption or delivery may increase linearly with synaptic activity in order to supply the required energy to the neurons. This principal may form the basis of fNIR spectroscopy use as a measurement of cognitive activity-related hemodynamic changes in the brain. Furthermore, since fNIR spectroscopy devices may be non-invasive, minimally intrusive, inexpensive, portable, and light-weight, it may be well suited for both field and clinical settings. FNIR spectroscopy may be successfully applied to many different target areas to detect changes in movement, visual, auditory, attention, memory, emotion, and executive functions of the brain. The technology is applicable to a variety of subjects, such as small children, the elderly, and sick persons due to its portable and non-invasive nature.

Measurement signals may be used in a variety of fields and applications to obtain information from a target or source. After obtaining a measurement signal, an observer may process and analyze the signal in order to obtain the data that is relevant to the observer. However, most analog measurement signals contain data in addition to the information that is relevant to the target measurement. For example, noise and other undesirable interference may be introduced into the measurement signal, thus increasing the difficulty of isolating the data of interest.

As an example, functional near infrared spectroscopy (fNIR spectroscopy) may be used to detect hemodynamic changes in the cerebral cortex. Specific frequencies of fNIR spectroscopy may be used to monitor hemoglobin levels in the cerebral cortex. It is often desirable to obtain these measurements in a field setting, for example in an operating room. However, fNIR spectroscopy measurements may be corrupted by a number of different physiological and/or non-physiological noise sources. These noise sources may include respiration, heart pulsation signals, motion, ambient light artifacts, and the like. If the noise associated with these sources of interference is not removed from the fNIR spectroscopy measurements, an observer may be unable to accurately determine the hemoglobin levels of the cerebral cortex.

In an exemplary embodiment, fNIR spectroscopy may be used to measure physiological responses related to cognitive activities. The information that reflects the underlying cognitive activity may be separated from non-cognitive noise artifacts. For example, fNIR spectroscopy measurements may be distorted by different physiological or non-physiological noise sources such as respiration signals, heart pulsations signals, equipment noise, motion artifacts and the like. This noise data, which is irrelevant to the cognitive-activity related hemodynamic signal, may be removed in order to obtain the most accurate and reliable measurement results.

One example of undesirable noise may be heart pulsation and respiration. Concentration of oxygenated (oxy-Hb) and deoxygenated (deoxy-Hb) hemoglobin as measured by fNIR spectroscopy may change due to respiration and heart pulsation regardless of any cognitive activity-related hemodynamic changes. For example, the mean frequency of respiration and heart pulsation signals for human adults is approximately 0.5 Hz and 1.2 Hz, respectively. Although the frequencies of the physiological signals may change for certain time periods, they still are different than the frequency range of hemodynamic signals related to cognitive activity. For example, some signals related to cognitive responses in the brain may have a frequency of up to 0.1 Hz. In this example, the higher frequency noise sources may be addressed through the use of low-pass filters, Weiner filters, and the like.

Another artifact that may corrupt fNIR spectroscopy and other types of measurements is motion artifacts. Head motion may cause the light sources or detectors on fNIR spectroscopy sensors to move or pop which may lead the light detectors to capture ambient light, reflected light from the skin, direct light from light sources, and/or the like. Noise due to head motion may be non-stationary in nature and may cause fluctuations in the data. Furthermore, the frequency range of the non-physiological artifacts may coincide with the frequency content of the hemodynamic response. Therefore it may be difficult to separate these noise sources from the signal of interest.

For example, in laboratory environments, subjects may be engaged with a cognitive task in a sitting position and to avoid motion artifacts subjects may use chin supports or maybe instructed to hold their heads still during the duration of the experiment. However, both of these procedures may be untenable in certain situations in which fNIR spectroscopy may be most advantageous. For example, portable field applications, mobile applications or conditions, and uncooperative or unconscious individuals may make avoiding motion artifacts impossible. In another example, during surgical procedures in operating room settings, the clinicians may need to change the position of patients and some patients may have uncontrolled movements during emergence from general anesthesia. Removal of this inevitable non-physiological noise from fNIR spectroscopy measurements or other signals may be extremely desirable for reliable assessment of cognitive activity in the brain.

In order to account for motion artifacts and other sources of signal noise, described herein is a technique that may combine and integrate ICA as well as PCA with an embedded hardware approach. The embedded hardware design may monitor each site recording independently and measure signals that are generated by noise within that local region. This technique may be applied to a variety of signals, and it is described herein with respect to fNIR spectroscopy for purposes of illustration.

ICA requires multi-channel measurements which are linear mixtures of multiple unknown source signals that should be statistically independent. ICA uses higher-order statistical information to find a suitable basis in such a way that the statistical independence between the projections of the signal on basis vectors is maximized. ICA may be implemented with multiple active channels to determine independent source signals. An active channel may be an fNIR spectroscopy channel wherein an active light source such as an Light Emitting Diode (LED) emits light at a wavelength that corresponds to a channel sensor. For example, an active 850 nm channel may correspond to a 850 nm sensor with an active LED that is emitting light with a wavelength of 850 nm in the region near the sensor.

PCA requires multi-channel measurements which are linear mixtures of multiple unknown source signals that should be uncorrelated. PCA uses second order statistics to separate a signal into uncorrelated components. PCA may be implemented with multiple active channels to determine uncorrelated source signals. An active channel may be an fNIR spectroscopy channel wherein an active light source such as an Light Emitting Diode (LED) emits light at a wavelength that corresponds to a channel sensor. For example, an active 850 nm channel may correspond to a 850 nm sensor with an active LED that is emitting light with a wavelength of 850 nm in the region near the sensor.

ICA assumes the existence of number of signals that are linear mixtures of a number of unknown independent source signals. For example, n may be the number of signals that are linear mixture of m unknown source signals. At time instant t, the observed n-dimension data vector may be expressed as:

x_{ICA}(t)=[x_{ICA1}(t) . . . x_{ICAn}(t)]^{T} (Eq. 1)

wherein x_{ICA}(t) may be the observed data vector, x_{ICA1}(t) may be the first component of the observed data, x_{ICAn}(t) may be the nth component of the observed data, and the superscript T represent the transpose. Similarly, Eq. 1 may be expressed as:

x_{ICA}(t)=[x_{ICAi}(t)]^{T}, where i=integers from 1 to N, inclusive (Eq. 2)

wherein N may be the number of observed data components. x_{ICA}(t) may be given by the model:

x_{ICA}(t)=A_{ICA}s_{ICA}(t) (Eq. 3)

wherein A_{ICA} is the ICA mixing matrix, and s_{ICA}(t) may be the independent sources signals which may be defined as:

s_{ICA}(t)=[s_{ICA1}(t) . . . s_{ICAm}(t)]^{T} (Eq. 4)

wherein s_{ICA1}(t) may be the first independent source component of the observed data, and s_{ICAm}(t) may be the mth independent source component of the observed data. Similarly, Eq. 4 may be expressed as:

s_{ICA}(t)=[s_{ICAj}(t)]_{T}, where j=integers from 1 to M, inclusive. (Eq. 5)

wherein, M may be the number of independent source components. Both the independent source signals and the coefficients of the mixing matrix A_{ICA} may be unknown. Conditions for the existence of a solution are when n is greater than or equal to m (i.e., there are at least as many mixtures as the number of independent sources), and up to one source may be Gaussian. Under these assumptions, ICA seeks a solution in the form:

ŝ_{ICA}(t)=B_{ICA}x_{ICA}(t) (Eq. 6)

where B_{ICA} may be called the ICA separating matrix, and ŝ_{ICA}(t) may be an ICA-estimated source signal. Additionally, the separating matrix may be given as the inverse of the estimated mixing matrix, mathematically represented as:

B_{ICA}=Â_{ICA}⁻¹ (Eq. 7)

ICA does not rely on the availability of clean reference channels to separate signals as in adaptive filtering. However, ICA performance may depend greatly on the ICA method selected. For example, several ICA algorithms such as second-order blind identification (SOBI), Infomax, and fICA have been developed and applied to EEG and MEG data. For purposes of illustration, fICA is used to demonstrate the performance of the combined ICA/PCA technique

PCA addresses a similar problem to ICA where the observed n-dimensional data vector may be defined as:

x_{PCA}(t)=[x_{PCA1}(t) . . . x_{PCAn}(t)]^{T} (Eq. 8)

wherein x_{PCA}(t) may be the observed data vector, x_{PCA1}(t) may be the first component of the observed data, and x_{PCAn}(t) may be the nth component of the observed data. Similarly, Eq. 8 may be expressed as:

x_{PCA}(t)=[x_{PCAi}(t)]^{T}, where i=integers from 1 to N, inclusive (Eq. 9)

wherein N may be the number of observed data components. x_{PCA}(t) may be given by the linear model:

x_{PCA}(t)=A_{PCA}s_{PCA}(t) (Eq. 10)

wherein A_{PCA} is the PCA mixing matrix, and s_{PCA}(t) may be the uncorrelated sources signals which may be defined as:

s_{PCA}(t)=[s_{PCA1}(t) . . . s_{PCAm}(t)]^{T} (Eq. 11)

wherein s_{PCA1}(t) may be the first uncorrelated source component of the observed data, and s_{PCAm}(t) may be the mth uncorrelated source component of the observed data. Similarly, Eq. 11 may be expressed as:

s_{PCA}(t)=[s_{PCAj}(t)]^{T}, where j=integers from 1 to M, inclusive (Eq. 12)

wherein M may be the number of uncorrelated source components. Both the uncorrelated source signals and the coefficients of the PCA mixing matrix, A_{PCA}, may be unknown. As in ICA, PCA seeks a solution of the form:

ŝ_{PCA}(t)=B_{PCA}x_{PCA}(t) (Eq. 13)

wherein B_{PCA} may be called the PCA separating matrix, and ŝ_{PCA}(t) may be a PCA-estimated source signal. Additionally, the separating matrix may be given by:

B_{PCA}=Â_{PCA}⁻¹ (Eq. 14)

However, unlike the condition in ICA that the sources be statistically independent, in PCA the sources should be uncorrelated. Therefore, PCA may estimate the unknown sources and the separating matrix using second order statistics based on singular value decomposition. The principle components may come from the eigenvectors of the covariance matrix of x_{PCA}(t), which may be the columns of a matrix E_{PCA} satisfying:

E_{PCA}D_{PCA}E_{PCA}⁻¹=<x_{PCA}x_{PCA}^{T}> (Eq. 15)

wherein D_{PCA} may be the diagonal matrix of eigenvalues. In this case, the separating matrix may be found as:

B_{PCA}=D_{PCA}^{(-1/2)}E_{PCA}^{T} (Eq. 16)

Since fNIR spectroscopy may be a multi-channel measurement, one approach may be to use different channels of the fNIR spectroscopy measurements as the inputs to an ICA and/or PCA analysis. However, in an example embodiment, each channel of the fNIR spectroscopy measurements may be analyzed with reference to a reference measurement (referred to herein as a dark current reference measurement) rather than a second active fNIR spectroscopy channel. The dark current reference may be a fNIR spectroscopy measurement with no active light source. For example, a fNIR spectroscopy sensor may detect light with a wavelength of 805 nm. However, if the 805 nm LED is not powered, the 805 nm detector may detect ambient light due to noise, rather than a cortical signal due to a hemodynamic response. Since the dark current reference signal detected by the sensor under such conditions may not contain cortical signals, it may be assumed that measurements corresponding to the dark current reference signal may be entirely due to the noise artifact.

Since each detector may measure the hemodynamic activity within the underlying local tissue that is located between the source and that detector, the hemodynamic signal received by each sensor may be slightly different than the signal received at a different sensor. Similarly, the artifact signal received by the sensor may be slightly different, or in some cases may not be present, at the sensor for each channel. Due to the variation in the measured signal level of an artifact detected over different channels, it may be desirable to remove the artifact from each channel separately. And, the use of the dark current reference signal allows each active channel to be evaluated independently.

An exemplary embodiment of removing noise artifacts may be hemodynamic monitoring using fNIR spectroscopy while a patient is under the influence of anesthesia. A sensor device may be applied to the patient's head prior to induction of anesthesia and may remain in place throughout the surgery. Data collection may commence prior to administration of sedative and other anesthetic medications, may continue throughout surgery, and may be halted after emergence from anesthesia. Disclosed herein is a flexible sensor that covers the entire forehead of the participant. The flexible sensor may be used in conjunction with a control box for data acquisition, a power supply for the control box, and a computer for the data analysis software. One skilled in the art will appreciate that these components may be combined or contained in independent machines and still be in accordance with an embodiment.

The computer used for data analysis may be implemented in connection with hardware, or hardware and software. Thus, the methods and apparatus described herein, or certain aspects or portions thereof, may take the form of program code (i.e., instructions) embodied in tangible media, such as floppy diskettes, CD-ROMs, hard drives, or any other machine-readable storage medium wherein, when the program code is loaded into and executed by a machine, such as a computer, the machine becomes an apparatus for implementing embodiments. In the case of program code execution on programmable computers, the computing device generally includes a processor, a storage medium readable by the processor (including volatile and non-volatile memory and/or storage elements), at least one input device, and at least one output device. A computer-readable storage medium, as described herein is an article of manufacture, and thus, not to be construed as a transitory signal. One or more programs that may implement or utilize the processes described in connection with the invention, e.g., through the use of an API, reusable controls, or the like. The computer language may be a compiled or interpreted language, and combined with hardware implementations.

Although exemplary embodiments may refer to utilizing techniques in the context of one or more stand-alone computer systems, the method is not so limited, but rather may be implemented in connection with any computing environment, such as a network or distributed computing environment. Still further, aspects of the method may be implemented in or across a plurality of processing chips or devices, and storage may similarly be effected across a plurality of devices. Such devices might include personal computers, network servers, handheld devices, supercomputers, or computers integrated into other systems such as automobiles and airplanes.

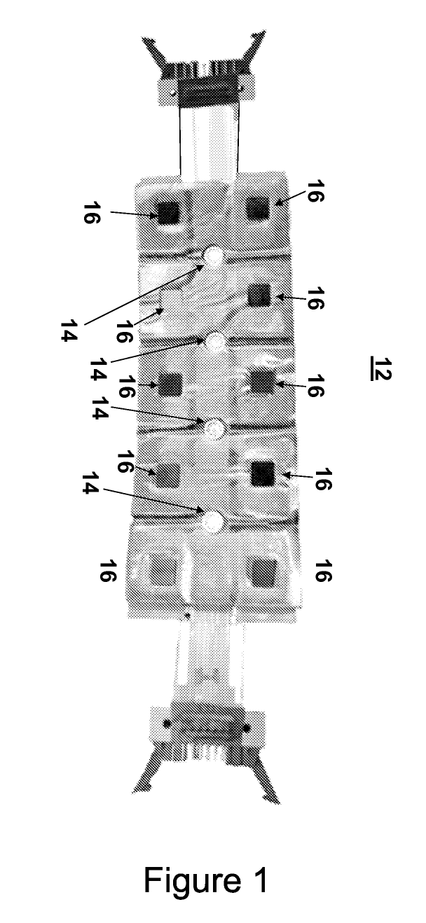

FIG. 1 depicts an example flexible sensor 12 for sensing fNIR signals. In an example embodiment, the sensor 12 comprises four led light sources 14 (which may be built in, detachable, or any appropriate combination thereof) and 10 detectors 16 which cover the forehead using 16 channels with a source-detector separation of approximately 2.5 cm. For example, the light sources may be at 730 nm, 805 nm and 850 nm wavelengths. The flexible sensor may be a modular design comprising a reusable, flexible circuit board that carries the infrared sources and detectors, and a cushioning material that serves to attach the sensor. An exemplary sampling rate of the fNIR spectroscopy system may be 2 Hz.

In a an example embodiment, the signals of interest may be obtained from two of the three wavelengths: 730 nm which may be associated with absorption due to deoxy-hemoglobin, and 850 nm which may be associated with absorption due to oxy-hemoglobin. The third LED, which may correspond to a wavelength of 805 nm, is not powered, and therefore no light is emitted from the 805 nm LED. The absence of light corresponds to a dark current condition. The measurements from the 805 nm sensor may be the dark current reference signal. The signal may be expected to be steady during the dark current condition, therefore it may be assumed that any signal changes during the dark current condition correspond to a noise artifact. The dark current condition may be used as a reference signal for the noise artifact.

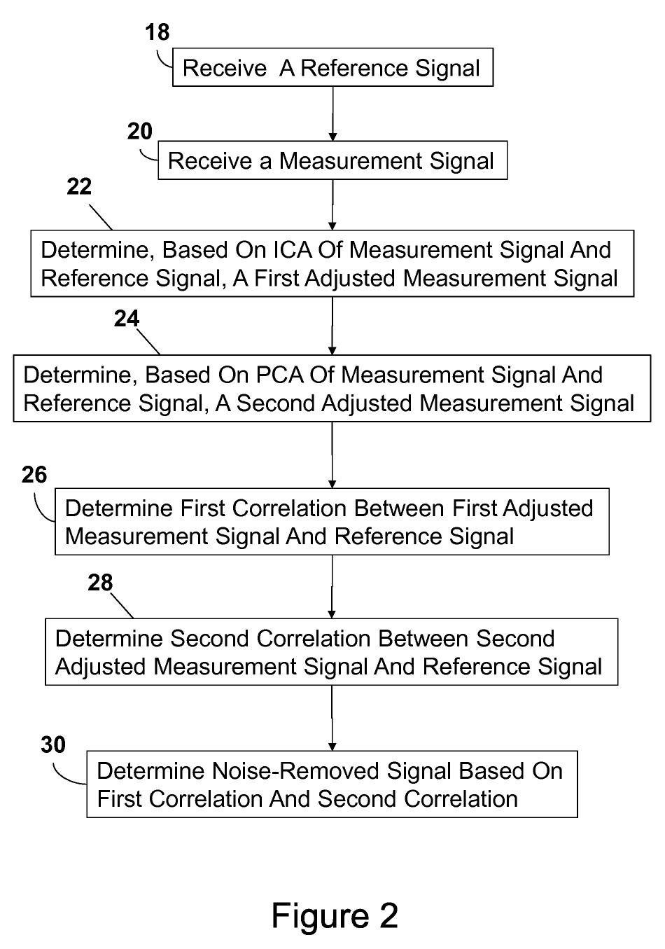

FIG. 2 is a flow diagram of an example noise removal process. A reference signal is received at step 18. The reference signal may be any appropriate reference signal. In an example embodiment, the reference signal may be the dark current reference signal described herein. A measurement signal may be received at step 20. The measurement signal may be any appropriate measurement signal. In an example embodiment, the measurement signal may be a fNIR signal, or combination of signals, as described herein. At step 22, a first adjusted measurement signal may be determined (calculated) based on an ICA of the measurement signal and the reference signal, as described herein. At step 24, a second adjusted measurement signal may be determined (calculated) based on a PCA of the measurement signal and the reference signal, as described herein. A first correlation between the first adjusted measurement signal and the reference signal, as described herein, may be determined at step 26. A second correlation between the second adjusted measurement signal and the reference signal, as described herein, may be determined at step 28. The noise-removed signal may be determined based on the first correlation and the second correlation, as described herein, at step 30.

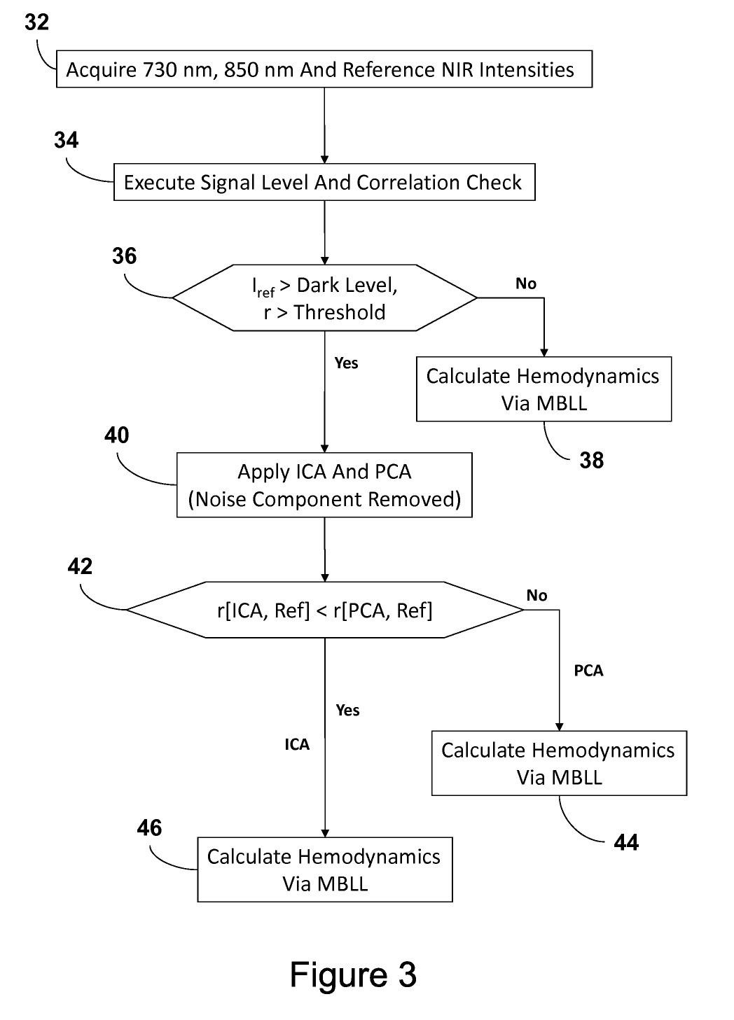

FIG. 3 is another flow diagram of example noise removal technique in accordance with an embodiment. The fNIR spectroscopy measurements may be obtained, for example at 730 nm and 850 nm. A reference signal may be obtained under dark current conditions. In an example embodiment, the level of the dark current condition reference signal may be examined prior to applying the component analysis procedures. In some cases, there may be minimal correlated changes in the active fNIR spectroscopy signals or no high intensity levels in the reference signal. In this case applying noise removal procedures to those cases may be unnecessary, and may also induce additional noise in the active fNIR spectroscopy measurements. For example, the ICA and PCA analyses may be applied where the correlation between an active fNIR spectroscopy measurement and the dark current reference signal, which may be denoted r, is above a predetermined threshold. For example, the ICA and PCA analysis may be applied if r>0.7, which may indicate that a noise artifact is present.

For example, as depicted in FIG. 3, FNIR spectroscopy measurements and reference measurements may be acquired at step 32. In an example embodiment, measurements at 730 nm, 805 nm, and/or 850 nm may be acquired. In an example configuration, the light sources in fNIR measurements may have three LEDs (730, 805 and 850 nm) to allow for spectroscopic measurements. Calculations for hemodynamic signals may be carried out using the measurements obtained from two of the three wavelengths. For example, measurements at wavelengths 730 nm which is associated with absorption due to deoxy-hemoglobin, and 850 nm which is associated with absorption due to oxy-hemoglobin, may be obtained. A wavelength of 805 nm may be used in the dark-current condition, i.e., no light is emitted at this wavelength, and therefore the detector may capture only signals that are generated by noise within that local region. Since the noise is local, it may provide reliable information about potential contaminates of the neural signal.

Signal level and correlation checks may be executed at step 34. Both ICA and PCA may be implemented to identify and to extract the measured correlated noise. To increase robustness and performance, the correlation between the dark current measurement and the recordings obtained at two wavelengths during the real-time measurement may be calculated. In an example embodiment, the correlation threshold may be set to (r=0.7) and the reference signal intensity may be above the dark current level for the application of ICA and PCA algorithms for noise removal. If the reference signal intensity (I_{ref}) is greater than the dark current level and the correlation threshold (r) is greater than the threshold (e.g., 0.7), as determined at step 36, ICA and PCA may be applied at step 40. Otherwise, hemodynamics may be calculated via the modified Beer-Lamber law (MBLL) at step 38.

As a result of the application of ICA and PCA at step 40, the noise component may be removed. Algorithm selection may be executed at step 42. The method (ICA or PCA) that performs better may be selected for automatic removal of all artifacts. In this example scenario, for each wavelength measurement either at 730 nm or 850 nm, a separate ICA and PCA algorithm may be performed where the measurement vector x(t) is two dimensional containing the measurement obtained either at 730 nm or at 850 nm and the one at the dark current. The unknown independent/uncorrelated source signals s(t) that is estimated by the ICA/PCA algorithm may also be two dimensional which may be the non-physiological noise signal and the clean raw intensity signal related with hemodynamic changes. Once the unknown A matrix and the unknown source signals s(t) are extracted, the noise signal may selected by correlating the independent components with the reference signal separately and selecting the one analysis giving the highest correlation. After the selection of the independent component corresponding to the noise signal, the noise may be removed from the original 730 nm or 850 nm recordings by subtracting it from that measurement with an appropriate amount found from the estimated A matrix. Correlation between the dark current measurement and the noise removed intensity measurements via ICA and PCA algorithms may be calculated separately.

The outcome of the best performing algorithm that generates lowest correlation may be selected as the cleaned raw intensity measurement, as depicted in step 42, 44, and 46. At step 42, the best performing algorithm in the removal of noise from the original 730 nm and 850 nm recordings may be found by correlating the noise removed signal obtained via ICA and PCA separately with the reference signal. If the outcome of the ICA algorithm provides smaller correlation with the original reference signal than the outcome of the PCA algorithm, the ICA algorithm may be selected as the best performing algorithm and its outcome may be selected as the noise removed intensity signal. Otherwise, the PCA algorithm may be selected as the best performing algorithm and its outcome may be selected as the noise removed intensity signal. Once the cleaned raw intensity measurements at 730 nm and 850 nm selected as the outcomes of the best performing algorithm via ICA or PCA are calculated separately, they can be used to calculate changes in hemodynamics in terms of oxygenated and deoxygenated hemoglobin using MBLL at steps 44 and 46.

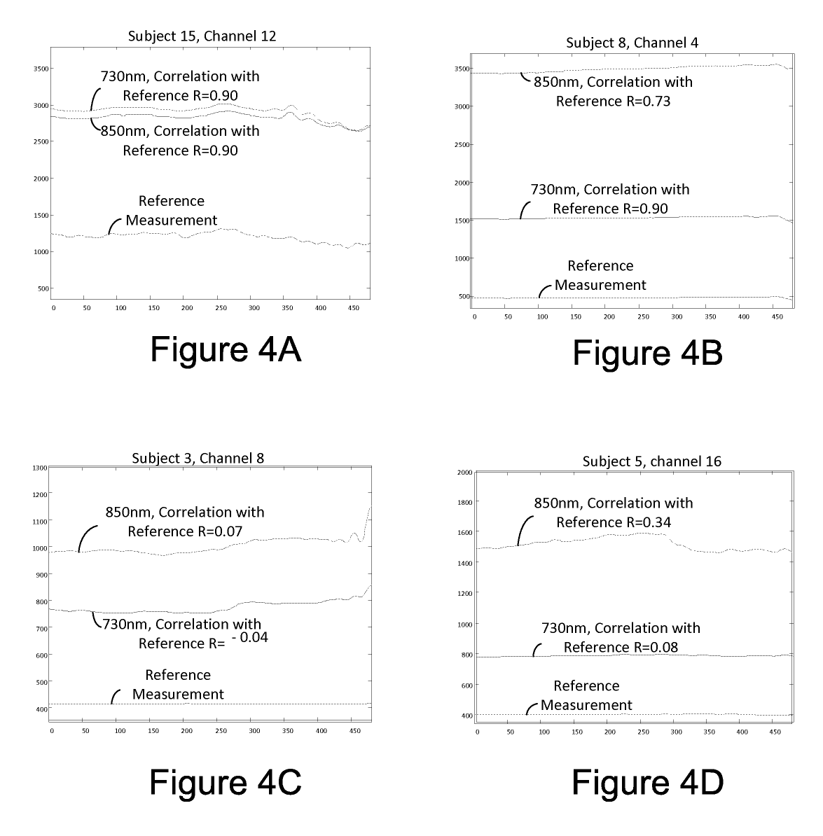

FIGS. 4A and 4B may correspond to the situation in which the correlation between the raw intensity measurements and the dark current condition reference signal is above 0.7, and may indicate that a noise artifact is present. FIGS. 4C and 4D may correspond to the situation in which the correlation between the raw intensity measurement signal and the dark current condition reference signal is below 0.7. In this exemplary embodiment, if the correlation is less than 0.7, it may be assumed that the noise artifact is not present, and hence the noise removal analysis is unnecessary. If it is determined that the correlation is above 0.7, then both the ICA and PCA analyses may be performed.

For the ICA and/or PCA analyses, the measurement vectors x_{ICA}(t) and x_{PCA}(t), respectively, may be two dimensional and may contain the measurements obtained at 730 nm and/or 850 nm as well as the dark current reference signal. For ICA, the unknown independent source signals s_{ICA}(t) that may be estimated by the ICA algorithm may also be two dimensional containing the noise and the cleaned raw intensity signal related to hemodynamic changes due to cognitive activity. Using ICA, the unknown matrix A_{ICA} and the unknown source signals s_{ICA}(t) may be calculated. A correlation analysis may be performed to identify the source signals. The correlation analysis may be used to determine whether a particular independent source component corresponds to noise or a cleaned raw intensity signal. The independent noise signal may be identified by calculating the correlation between each independent source signal, s_{ICA}(t), and the dark current reference signal. In an embodiment, the noise signal is selected by calculating the correlation between each independent source signal and the dark current reference signal. The independent source with the highest correlation with the dark current reference signal may then be selected as the independent noise source. After selection of the independent component corresponding to the noise signal, the noise may be removed from the original signal by subtracting the identified noise signal from a particular measurement using a value determined from the estimated A_{ICA} matrix.

Following a similar procedure for the PCA as the ICA, the noise signal and signal related to the brain activity may be obtained using the PCA analysis under the assumption that all sources are uncorrelated. Similarly, s_{PCA}(t), which may correspond to the uncorrelated source signals and A_{PCA}, which may be the PCA mixing matrix, may be obtained. The noise may be removed from the raw intensity measurements at 730 nm and/or 850 nm individually by following a similar procedure to that of the ICA approach. As was the case in the ICA analysis, the source signal with the highest correlation to the dark current reference signal may be identified as the noise source.

In an embodiment, once the unknown A matrix and the unknown sources signals s(t) are estimated using the ICA and PCA analyses, the ICA and PCA corrected measurement signals may be calculated. The ICA corrected measurement may be calculated by subtracting the independent source associated with the noise from the measurement corresponding to that source signal using a value determined from the estimated A_{ICA}. Similarly, the PCA corrected measurement may be calculated by subtracting the uncorrelated source associated with the noise from the measurement corresponding to that source signal using a value determined from the estimated A_{PCA}. Thus, the result of the subtraction may yield an ICA-adjusted clean measurement signal and a PCA-adjusted clean measurement signal.

The correlation between the dark current reference signal and the ICA-adjusted clean measurement signal may then be calculated. Similarly, the correlation between the dark current reference signal the PCA-adjusted clean measurement signal may be calculated. In an embodiment, if the correlation between the ICA-adjusted clean measurement signal and the dark current reference signal is higher than the correlation between the PCA-adjusted clean measurement signal and the dark current reference signal, then the PCA-adjusted clean measurement signal may be selected as the measurement signal with the noise artifact removed. If the correlation between the PCA-adjusted clean measurement signal and the dark current reference signal is higher than the correlation between the ICA-adjusted clean measurement signal and the dark current reference signal, then the ICA-adjusted clean measurement signal may be selected as the measurement signal with the noise artifact removed.

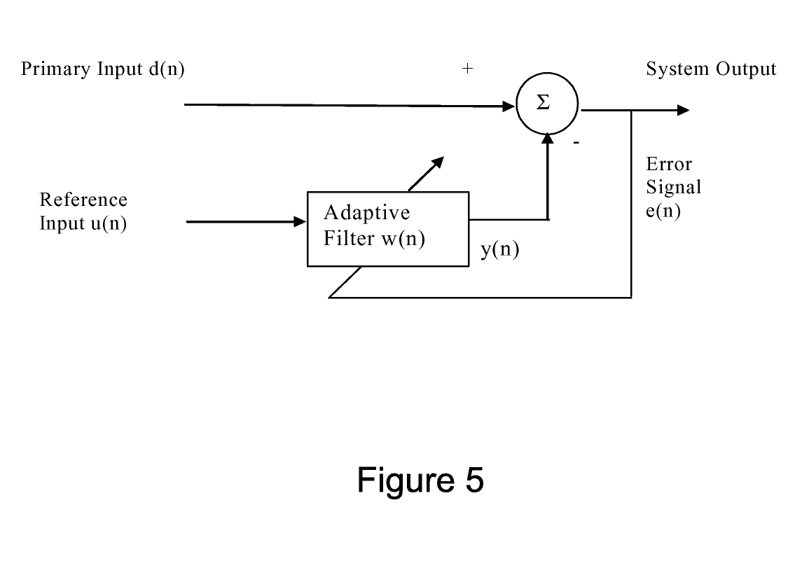

In order to evaluate the effectiveness of the ICA and PCA approaches, the data signals may be filtered using an adaptive filtering (AF) approach and the results of each analysis may be compared. There are several different adaptive filtering techniques such as least mean square (LMS) adaptive filters, normalized least mean square (NLMS) adaptive filters, recursive least squares (RLS) adaptive filter, and the like. A block diagram of a typical LMS type adaptive filter is shown in FIG. 5. The primary input d(n) may be the original signal plus the noise artifact. The reference input u(n), which may be a correlated signal with the artifact as part of the primary input, may be obtained from a separate measurement. Using the adaptive filtering approach, the filter coefficients w(n) may be updated at each time point n using d(n) and u(n) to estimate the signal y(n) which may be an estimate of the artifact within d(n). The estimated original signal e(n) may be estimated by:

e(n)=d(n)−y(n) (Eq. 13)

In order to correctly apply adaptive filtering, a reference signal for the effects of noise that is correlated with the artifacts within the measurements may be needed. For purposes of illustration, the dark current reference signal may be used as the reference signal, although other signals representing the artifact may be used as the reference signal. In an embodiment, the raw intensity measurements collected at 730 nm and 850 nm may be used for the primary input d(n). Although NLMS type adaptive filtering may be used due to its computational simplicity and faster convergence rate, other types of adaptive filtering may be used.

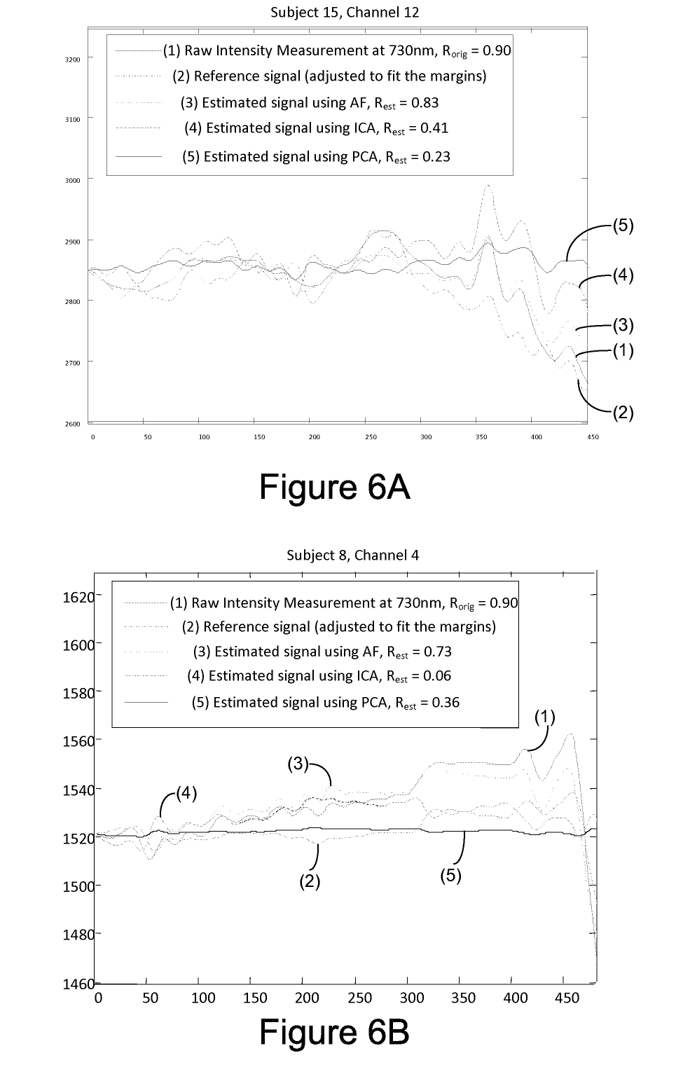

To evaluate the effectiveness of the noise removal approach, the ICA/PCA analysis was compared to the results obtained using a traditional adaptive filtering (AF) approach. An example of the results of the proposed techniques are presented in FIGS. 6A and 6B. FIG. 6A corresponds to the data set in FIG. 4A and FIG. 6B corresponds to the data set presented in FIG. 4B. The original 730 nm raw measurement signal, the dark current reference signal, and the cleaned measurements using the AF, ICA and PCA techniques are included in FIGS. 6A and 6B. In order to quantitatively compare the performances of the proposed algorithms, a performance measure may be used based on the correlation between the reference signal and the cleaned measurement signal at 730 nm or 850 nm as estimated by each component analysis. This correlation may be referred to a Rₑₛₜ. Since the noise within the original raw measurement signal is reduced in the cleaned measurement signals, the correlation of the cleaned signals with the dark current condition reference signal may be the lowest for the best performing technique.

As can be seen by visual inspection of FIGS. 6A and 6B, the AF approach was not as effective in suppressing the noise as the ICA or PCA approaches. In the example given in FIG. 6A, PCA performed better in suppressing the noise and the R_{estPCA}=0.23 was the lowest correlation of the applied approaches. In the example shown in FIG. 6B, ICA was the best performing technique with R_{estICA}=0.06. The above described approach was performed on 26 subjects using 16 channels and 2 wavelengths for a total of 832 recordings. Of the 832 recordings, the correlation between the raw measurement signal and the dark current reference signal exceeded 0.7 in 310 cases. The ICA and PCA analysis were performed on the 310 cases to validate the component analysis selection technique.

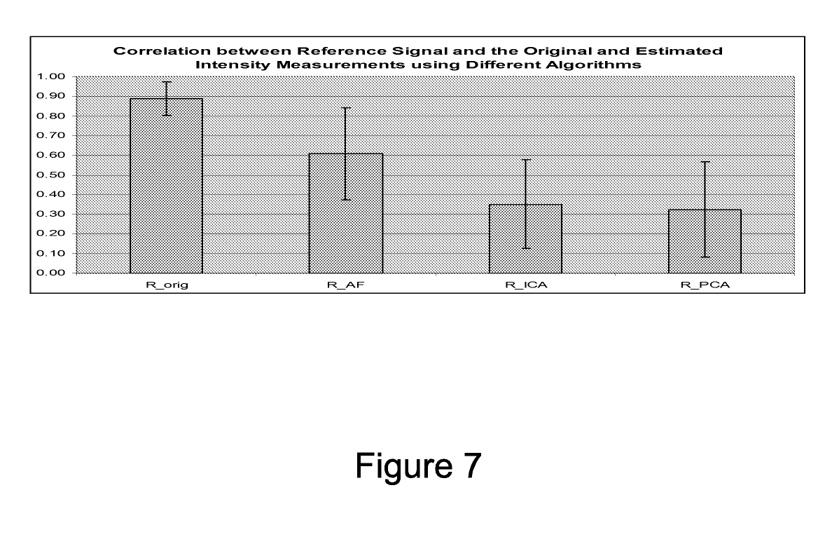

FIG. 7 presents the mean value and the standard deviation of R_{orig} (The original correlation between the raw measurement signal and the dark current reference signal), and the Rₑₛₜ that may be calculated from the results obtained from the ICA, PCA and AF techniques. The value of Rₑₛₜ, which represents the correlation between the cleaned measurement signal and the dark current reference signal, was on average higher for AF than for ICA or PCA. The mean correlation value for both the ICA and PCA approaches were comparable, which may suggest that both the ICA and PCA approaches outperform AF.

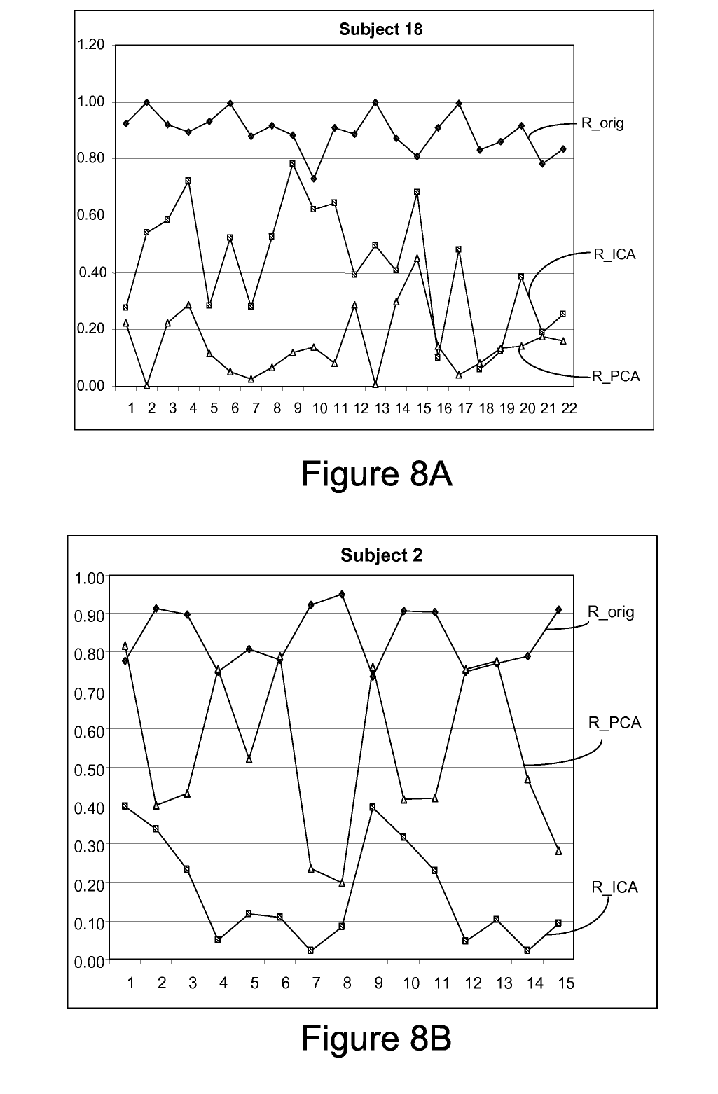

FIGS. 8A and 8B are example graphs showing Rₑₛₜ, the correlation between the signal of interest (i.e., the cleaned measurement signal) and the dark current reference signal. FIGS. 8A and 8B include the correlation between the dark current reference signal and 1) the original raw measurement signal, 2) a cleaned signal after the ICA technique has been applied, and 3) a cleaned signal after the PCA technique has been applied. FIG. 8A corresponds to the data set presented in FIG. 6A and FIG. 8B corresponds to the data set presented in FIG. 6B. As can be seen in FIG. 8A, PCA was the best performing algorithm. As can be seen in FIG. 8B, ICA was the best performing algorithm. This confirms that a selection procedure between the two algorithms may yield the best overall results for a large variety of data. The differences in performance between the data sets may be due to violations of the assumptions of the underlying analyses, such as lack of independence in ICA or a presence of higher order statistical independence other than just the uncorrelatedness between sources in PCA.

Furthermore, it should be emphasized that a variety of computer platforms, including handheld device operating systems and other application specific operating systems are contemplated. Still further, the potential embodiments may be implemented in or across a plurality of processing chips or devices, and storage may similarly be affected across a plurality of devices. Moreover, computer-executable instructions for performing the methods described herein may be stored on a computer readable storage medium such as, for example, a USB drive, RAM, ROM, CD or other storage device.

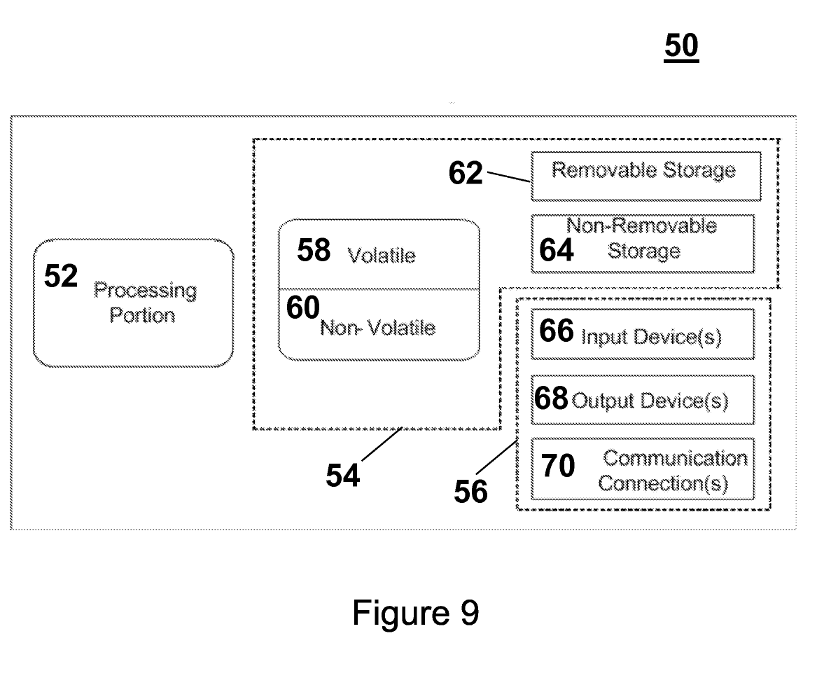

FIG. 9 is a block diagram which illustrates an exemplary computing device 50 configurable to facilitate real time artifact removal as described herein. In an example embodiment, the computing device 50 comprises hardware, or a combination of hardware and software. And, each portion of the computing device 50 comprises hardware, or a combination of hardware and software. The functionality needed to facilitate real time artifact removal may reside in any one or combination of network entities. It is emphasized that the block diagram depicted in FIG. 9 is exemplary and not intended to imply a specific implementation or configuration. Thus, the computing device 50 can be implemented in a single processor or multiple processors. Multiple processors can be distributed or centrally located. Multiple processors can communicate wirelessly, via hard wire, or a combination thereof.

In an example configuration, the computing device 50 comprises a processing portion 52, a memory portion 54, and an input/output portion 56. The processing portion 52, memory portion 54, and input/output portion 56 may be coupled together (coupling not shown in FIG. 9) to allow communications therebetween. The input/output portion 56 may be capable of receiving and/or providing information from/to a device (e.g., the sensor depicted in FIG. 1) and/or other units configured to implement real time artifact removal. For example, the input/output portion 56 may be capable of, in conjunction with any other portion of the computing device 50 as needed, receiving and/or sending signals associated with cognitive activity, signals associated with artifacts, dark current reference signals, processed and/or cleaned signals or any combination thereof. As may be appreciated, the signals described herein may be represented as voltages, currents, power levels, intensities, or the like.

The processing portion 52 may be capable of performing functions associated with real time artifact removal, as described herein. For example, the processing portion 52 may be capable of, in conjunction with any other portion of the computing device 50 as needed, executing an application for facilitating real time artifact removal. The memory portion 54 may store any information utilized in conjunction with facilitating real time artifact removal. For example, the memory portion 54 may be capable of storing information pertaining to the received signals, components of the received signals, components of the processed signals, the results of an ICA analysis, the results of a PCA analysis, correlations of signals and the like. Depending upon the exact configuration and type of computing device 50, the memory portion 54 may include a computer storage medium, or media, that is volatile 58 (such as dynamic RAM), non-volatile 60 (such as ROM), or a combination thereof. The computing device 50 may include additional storage, in the form of computer storage media (e.g., removable storage 62 and/or non-removable storage 64) including, RAM, ROM, EEPROM, tape, flash memory, smart cards, CD-ROM, digital versatile disks (DVD) or other optical storage, magnetic cassettes, magnetic tape, magnetic disk storage or other magnetic storage devices, universal serial bus (USB) compatible memory. As described herein, a computer storage medium is an article of manufacture and not to be construed as a transient signal.

The computing device 50 also may contain communications connection(s) 70 that allow the computing device 50 to communicate with other computing devices, or the like. A communications connection(s) 70 may comprise communication media. Communication media may be used to communicate computer readable instructions, data structures, program modules, or other data. Communication media may include an appropriate transport mechanism or information delivery media that can be used to transport a modulated data signal such as a carrier wave. The computing device 50 also may include input device(s) 66 such as keyboard, mouse, pen, voice input device, touch input device, an optical input device, etc. Output device(s) 68 such as a display, speakers, printer, mechanical vibrators, etc. also may be included.

The preceding paragraphs describe various embodiments for removal of noise artifacts from signals of interest. Although the artifact removal technique is described with reference to fNIR spectroscopy measurements, the above described technique can be applied to a variety of signal sources in a variety of applications. While the disclosure has been described in connection with the exemplary embodiments of the various figures, it is not limited thereto and it is to be understood that other similar embodiments may be used or modifications and additions may be made to the described embodiments for performing the same function as those described without deviating therefrom.

Therefore, the present disclosure should not be limited to any single embodiment, but rather should be construed in breadth and scope in accordance with the appended claims. Also, the appended claims should be construed to include other variants and embodiments, which may be made by those skilled in the art without departing from the true spirit and scope of the herein disclosed system.

What is claimed:

1. A method comprising:
receiving a reference signal and a measurement signal;
determining, based on a first component analysis of the measurement signal and the reference signal, a first adjusted measurement signal;
determining, based on a second component analysis of the measurement signal and the reference signal, a second adjusted measurement signal;
determining a correlation between the first adjusted measurement signal and the reference signal;
determining a correlation between the second adjusted measurement signal and the reference signal; and
determining a noise-removed signal based on:
the correlation between the first adjusted measurement signal and the reference signal; and
the correlation between the second adjusted measurement signal and the reference signal.

2. The method of claim 1, wherein:
the first component analysis comprises an independent component analysis (ICA); and
the second component analysis comprises a principle component analysis (PCA).

3. The method of claim 1, further comprising:
identifying the first adjusted measurement as the noise-removed signal when the correlation between the first adjusted measurement signal and the reference signal is less than the correlation between the second adjusted measurement signal and the reference signal; and
identifying the second adjusted measurement as the noise-removed signal when the correlation between the second adjusted measurement signal and the reference signal is less than the correlation between the first adjusted measurement signal and the reference signal.

4. The method of claim 1, wherein:
the reference signal corresponds to a signal obtained when a light source was not active.

5. The method of claim 1, wherein:
identifying the first adjusted measurement signal comprises subtracting a source signal with a highest correlation to the reference signal from the measurement signal.

6. The method of claim 1, wherein:
identifying the second adjusted measurement signal comprises subtracting a source signal with a greatest correlation to the reference signal from the measurement signal.

7. The method of claim 1, further comprising:
determining if a correlation between the measurement signal and the reference signal is greater than a predetermined threshold.

8. A computer-readable storage medium having stored thereon executable instructions that when executed perform operations comprising:
receiving a reference signal and a measurement signal;
determining, based on a first component analysis of the measurement signal and the reference signal, a first adjusted measurement signal;
determining, based on a second component analysis of the measurement signal and the reference signal, a second adjusted measurement signal;
determining a correlation between the first adjusted measurement signal and the reference signal;
determining a correlation between the second adjusted measurement signal and the reference signal; and
determining a noise-removed signal based on:
the correlation between the first adjusted measurement signal and the reference signal; and
the correlation between the second adjusted measurement signal and the reference signal.

9. The computer-readable storage medium of claim 8, wherein:
the first component analysis comprises an independent component analysis (ICA); and
the second component analysis comprises a principle component analysis (PCA).

10. The computer-readable storage medium of claim 8, the operations further comprising:
identifying the first adjusted measurement as the noise-removed signal when the correlation between the first adjusted measurement signal and the reference signal is less than the correlation between the second adjusted measurement signal and the reference signal; and
identifying the second adjusted measurement as the noise-removed signal when the correlation between the second adjusted measurement signal and the reference signal is less than the correlation between the first adjusted measurement signal and the reference signal.

11. The computer-readable storage medium of claim 8, wherein:
the reference signal corresponds to a signal obtained when a light source was not active.

12. The computer-readable storage medium of claim 8, wherein:
identifying the first adjusted measurement signal comprises subtracting a source signal with a highest correlation to the reference signal from the measurement signal.

13. The computer-readable storage medium of claim 8, wherein:
identifying the second adjusted measurement signal comprises subtracting a source signal with a greatest correlation to the reference signal from the measurement signal.

14. The computer-readable storage medium of claim 8, the operations further comprising:
determining if a correlation between the measurement signal and the reference signal is greater than a predetermined threshold.

15. A computing device comprising:
memory having executable instructions stored thereon;
a processor communicatively coupled to the memory, the processor configure to execute the executable to perform operations comprising:
receiving a reference signal and a measurement signal;
determining, based on a first component analysis of the measurement signal and the reference signal, a first adjusted measurement signal;
determining, based on a second component analysis of the measurement signal and the reference signal, a second adjusted measurement signal;
determining a correlation between the first adjusted measurement signal and the reference signal;
determining a correlation between the second adjusted measurement signal and the reference signal; and
determining a noise-removed signal based on:
the correlation between the first adjusted measurement signal and the reference signal; and
the correlation between the second adjusted measurement signal and the reference signal.

16. The device of claim 15, wherein:
the first component analysis comprises an independent component analysis (ICA); and
the second component analysis comprises a principle component analysis (PCA).

17. The device of claim 15, the operations further comprising:
identifying the first adjusted measurement as the noise-removed signal when the correlation between the first adjusted measurement signal and the reference signal is less than the correlation between the second adjusted measurement signal and the reference signal; and
identifying the second adjusted measurement as the noise-removed signal when the correlation between the second adjusted measurement signal and the reference signal is less than the correlation between the first adjusted measurement signal and the reference signal.

18. The device of claim 15, wherein:
the reference signal corresponds to a signal obtained when a light source was not active.

19. The device of claim 15, wherein:
identifying the first adjusted measurement signal comprises subtracting a source signal with a highest correlation to the reference signal from the measurement signal.

20. The device of claim 15, wherein:
identifying the second adjusted measurement signal comprises subtracting a source signal with a greatest correlation to the reference signal from the measurement signal.
